(19) United States
(12) Patent Application Publication
(10) Pub. No.: US 2008/0190483 A1
(43) Pub. Date: Aug. 14, 2008

(54) Composition and method of preparing nanoscale thin film photovoltaic materials

(76) Inventors: R. Douglas Carpenter, Tustin, CA (US); Kevin D. Maloney, Newport Beach, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/706,899

(22) Filed: Feb. 13, 2007

(51) Int. Cl. H01L 31/0216; B22F 3/10

(52) U.S. Cl. 136/256; 419/38; 420/591; 428/546

(57) ABSTRACT

A photo-absorbing layer for use in an electronic device; the layer including metal alloy nanoparticles copper, indium and/or gallium made preferably from a vapor condensation process or other suitable process, the layer also including elemental selenium and/or sulfur heated at temperatures sufficient to permit reaction between the nanoparticles and the selenium and/or sulfur to form a substantially fused layer. The reaction may result in the formation of a chalcopyrite material. The layer has been shown to be an efficient solar energy absorber for use in photovoltaic cells.

### BACKGROUND OF THE INVENTION

1. Technical Field

The inventions disclosed herein relate generally to the manufacture of materials for thin film photovoltaic cells. More specifically, the invention relates to an improved production process for making the active absorbing material containing metal alloy nanoparticles that allows for increased efficiency, reduced cost, and reduced weight.

2. Related Art

A photovoltaic cell is a device that converts light energy directly into electricity. The high cost of polysilicon and resultant high cost of silicon solar cells has prevented widespread use of solar energy. Recent advances in low cost, high efficiency, thin film polycrystalline solar cells based on copper-indium-gallium-selenium-sulfide (CIGS) absorption layers promises to make solar energy competitive with energy derived from fossil fuels. Although these materials have some of the highest efficiencies of all classes of solar cells, exceeding 15%, several steps in the production process of CIGS solar cells are toxic and/or expensive. Additionally, with thicker active CIGS layers in a photovoltaic device, there is an increase chanced of layer defects that could lower overall cell efficiency.

These limitations present a roadblock to safe and cost-efficient mass-manufacture. The present invention is helpful in overcoming at least some of these deficiencies. For example, preparing a layer with reduced thickness is one key aspect to improve photovoltaic efficiency and to reduce materials cost. An additional benefit to using a thinner CIGS layer is a decreased weight contribution, which is critical in space applications.

### SUMMARY OF THE INVENTION

In some embodiments of the current invention, a photovoltaic cell has been prepared incorporating a photon-absorbing layer on an electrically conductive substrate in which the photon absorbing layer is comprised of metal alloy nanoparticles having the formula, for example, Cu₁In₁₋ₓGaₓ, where x equals from 0 to 1. In an inventive method of manufacture, the metal alloy nanoparticles are heated on the substrate in the presence of elements such as, for example, selenium and/or sulfur to a temperature sufficiently high to permit reaction, and preferably, become fused together to form a thin layer on the electrically conductive substrate to provide at least a portion of an electrical circuit that permits the flow of electrons. Preferably, this layer is less than 1 micron in thickness and, more preferably, the layer is less than about 500 nanometers.

In accordance with at least one of the preferred embodiments disclosed herein, a copper-indium-gallium (CIG) alloy was prepared utilizing facile manufacturing conditions. For example, but without limitation, copper-indium-gallium alloy can be selenized and/or sulfidized with elemental selenium and/or sulfur to form a photon-absorbing material, where by the resulting layer has a thickness of no more than about 1 micron, but preferably much less than 1 micron.

At least some of the embodiments of the present invention benefit from the presence of an increased number of reactive atoms exist at the surface of a nanoparticle. As such, metal alloy nanoparticles and their oxides can be utilized for further alloying under favorable reaction conditions. Metal alloy nanoparticles used in the described method in the preferred embodiments are from groups IB, IIB, or IIIA on the periodic table have a diameter of less than 50 nm. More preferably, the metal alloy nanoparticles are comprised of copper and indium, and most preferably copper-indium-gallium (CIG).

In at least one embodiment of the present invention, a photovoltaic device comprises an emitting layer is applied to the photon-absorbing layer. Preferably, the emitting layer is comprised of a material that is highly efficient at electron transport from the photon-absorbing layer, and most preferably comprises cadmium sulfide or similar molecule. On top of the emitting layer, an anti-reflective coating may be applied. In some of the preferred embodiments, the anti-reflective coating is both optically and electrically conductive to permit sunlight to reach the emitting layer effectively. The anti-reflective coating may preferably be zinc oxide.

In other preferred embodiments, an environmental protection layer is provided to provide weather-resistant properties to the device. Preferably, the environmental protection layer has optical and electrical conductive property, and may preferably comprise low-iron glass.

In one application of the present inventive process, a method of preparing a photon-absorbing layer of nanosized material is contemplated. One such method comprises heating metal alloy nanoparticles, prepared for example from a vapor condensation process, with at least one element selected from Groups VA and/or VIA on an electrically conductive substrate. Preferably, the nanosized material in the photon-absorbing layer is prepared by a vapor condensation process. An example of such a process is described in U.S. Pat. No. ______ [Ser. No. 10/840,109], which is incorporated herein in its entirety by reference. Other methods for obtaining beneficial photon-absorbing layers for use in effective photovoltaic devices may be employed. The composition is heated sufficiently high to permit reaction and create a substantially fused layer of nanosized particles. More preferably, the resulting layer is photon-absorbing for effective use in a photovoltaic device, and may comprise chalcopyrite.

In addition, it is preferable that a substantial portion of the metal alloy nanoparticles used in the method are less than 100 nm, and most preferably less than 50 nm. Utilization of the preferred particle size increases uniformity of the resulting layer after the heating step.

During the heating step, it is preferred that the mixture be heated to a temperature such that there is sufficient reaction between the metal alloy nanoparticles and at least one element selected from groups VA and/or VIA. Most preferably, the temperature should be at least 250° C.

In some of the embodiments, the temperature must be sufficient form a substantially fused layer of nanoparticles. It is more preferable that the layer be uniform and thin, most preferably less than 500 nm in thickness.

Some of the preferred embodiments detail the composition of a photovoltaic absorbing chalcopyrite material prepared from metal alloy nanoparticles. Preferably, the nano-scale metal alloy particles are comprised of at least copper and indium, and more preferably copper, indium, and gallium.

According to some of the embodiments in the current invention, a composition comprising metal alloy nanoparticles prepared from a vapor condensation process can be prepared for use in an electronic device. The metal alloy nanoparticles are preferably comprised from at least one metal from Groups IB, IIB, and/or IIIA, and arc most preferably at least one of copper, indium, and/or gallium.

Preferably, the metal alloy nanoparticles should have sufficiently high reactivity to permit reaction with elements from either Group VA and/or VIA in the gas, most preferably with selenium and/or sulfur in the liquid, or solid state. Thus, to permit this reaction, the particles should have a size of less than 100 nm, and most preferably less than 50 nm. At least some of the metal alloy nanoparticles have an oxide shell.

In other preferred embodiments, a photovoltaic cell comprising a photon-absorbing layer, electronically conductive substrate, emitting layer, and anti-reflective coating is described. The photon-absorbing layer is preferably comprised of copper-indium nanoparticles, and most preferably comprised of copper-indium-gallium nanoparticles. The nanoparticles are substantially fused together, prepared by heating metal alloy nanoparticles sufficiently to permit reaction preferably with material from either Group VA and/or VIA, and most preferably with selenium and/or sulfur.

The photon-absorbing layer is supported on an electronically conductive substrate which provides a portion of an electrical circuit in combination with the photon-absorbing layer. Preferably, this layer is thin and continuous, and most preferably less than 500 nm thick.

An emitting layer is applied directly to the photon-absorbing layer. Preferably, the emitting layer is comprised of a material that is highly efficient at electron transport from the photon-absorbing layer, most preferably cadmium sulfide. An anti-reflective coating is applied directly to the emitting layer. Preferably, an anti-reflective coating is both optically and electrically conductive to permit sunlight to enter the emitting layer, and most preferably is zinc oxide.

Additionally, the composition may also comprise an environmental protection layer. Preferably, this layer is comprised of material that reduces damage cause by weathering, and is most preferably composed of low-iron glass.

Some of the preferred embodiments detail stratified layers of metal alloy nanoparticles, comprising the formula Cu₁In₁₋ₓGaₓ, wherein x can vary from 0 to 1. Preferably, the gallium concentration in at least one of the stratifications is different from the gallium concentration in another stratification, and most preferably the concentration of gallium is lower proximal to the emitting layer.

At least some of the preferred embodiments describe at least three and up to twenty stratifications. The layer thickness of all stratifications combined should be thin and continuous, preferably the combined thickness is less than one micron, and most preferably less than 500 nm.

### BRIEF DESCRIPTION OF THE DRAWINGS

The features mentioned above in the summary of the invention, along with other features of the inventions disclosed herein, are described below with reference to the drawings of the preferred embodiments. The illustrated embodiments in the figures listed below are intended to illustrate, but not to limit the inventions.

FIG. 1 is a schematic of a thin film solar cell described in some of the embodiments.

### DETAILED DESCRIPTION OF SOME PREFERRED EMBODIMENTS

The features mentioned above in the summary of the invention, along with other features of the inventions disclosed herein, are described below with reference to the drawings of the preferred embodiments. The illustrated embodiments in the figures listed below are intended to illustrate, but not to limit the inventions.

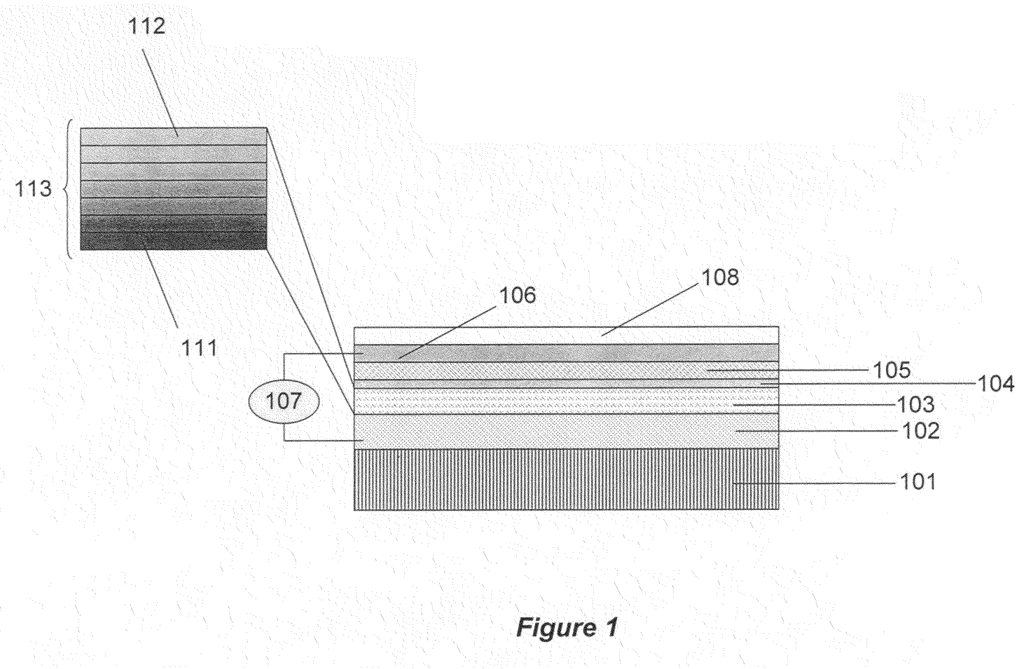

A photovoltaic (PV) cell is a device that converts solar energy directly into electricity. While there are several different classes of solar cells, the present invention has particular but not exclusive applicability to thin film solar cells made from materials such as copper-indium-gallium diselenide (CIGS) or copper-indium-gallium-selenium sulfide (CIGSS). Unlike traditional Si-based solar cells, CIGS and CIGSS cells are flexible and are more acceptable for a wider variety of surface profiles, such as curved or contoured surfaces. The diagram in FIG. 1 shows at least some of the different layers in, for example, a CIGS- or CIGSS-based solar cell. Base material 101 may be glass or metal foil, although a material having some plastic and/or elastic characteristic is preferable so that the cells permit increased flexibility. Upon the base material, substrate foil 102 may be deposited and can be used as a back contact. The substrate foil 102 is preferably a metal foil and may preferably comprise molybdenum. A photon-absorbing CIGS or CIGSS layer 103 may then be deposited onto foil 102. The thickness of this layer is highly dependent on how CIGS is applied to the surface. While the thickness of a typical CIGS cell is about two or so microns, the present inventive photon-absorbing layer 103 has an average thickness of less than one micron and preferably less than about 500 nm on average and most preferably a maximum thickness of about 500 nanometers. The CIGS layer is preferably formed as a p-type, photon-absorbing, layer based upon the particular arrangement of copper, indium, and gallium atoms.

To enhance the flow of electrons through the cell, an n-type electron transporting emission layer 104 can be applied to the photon-absorbing layer 103, preferably a layer comprising cadmium sulfide. An anti-reflective coating of zinc oxide 105 may be applied to the emission layer 104. Preferably, the anti-reflective layer is both electrically and optically conductive, allowing photons to reach the photon-absorbing layer 103. Electrical contact 106 may be applied to complete circuit 107 with foil 102 to collect and use the energy gained from light absorption. If desired, an environmental protection layer 108 may be placed on top the anti-reflective coating 106 and electrical contact 105 to minimize the effects of weathering of the photovoltaic device.

The present invention benefits from increased surface area of the reactive metal alloy nanoparticles, as compared to the surface area of the metal substrate particles, primarily due to the large number of atoms on the surface of the nanoparticles. As an example, a cube comprising a plurality of three nanometer nickel particles considered essentially as tiny spheres. As such, they would have about ten atoms on each side, about one thousand atoms in total. Of those thousand atoms, 488 atoms would be on the exterior surface and 512 atoms on the interior of the particle. This means that roughly half of the nanoparticles would have the energy of the bulk material and half would have higher energy due to the absence of neighboring atoms (nickel atoms in the bulk material have about twelve nearest neighbors while those on the surface has nine or fewer). A three micron sphere of nickel would have 10,000 atoms along each side for a total of one trillion atoms. There would be 999.4 billion of those atoms in the bulk (low energy interior) material. That means that only 0.06% of the atoms would be on the surface of the three micron-sized material compared to the 48.8% of the atoms at the surface of the three nanometer nickel particles.

Depending upon the process of manufacture, the metal alloy nanoparticles can be configured to have a surface energy sufficiently high to react with other elements under benign reaction conditions. For example, micron sized copper-indium-gallium (CIG) alloy particles have a lower surface energy density and would not react with elemental selenium or sulfur at temperatures below 750° C. Typically, highly reactive and toxic H₂Se or H₂S gasses would be necessary to complete this reaction. However, CIG alloy nanoparticles, including those as small as 50 nanometers, can react with elemental materials such as selenium and/or sulfur at 250° C. to produce CIGS or CIGSS, both photon-absorbing materials. As such, metal alloy nanoparticles have been shown to have exponentially higher surface area-to-volume ratio than that of a micron-scale metal alloy particle. Thus, CIGS or CIGSS material can be produced under more gentle, environmentally friendly conditions by virtue of the increased reactivity of nanoscale CIG. Layers comprising CIGS and CIGSS materials may form chalcopyrites.

When the CIG metal alloy nanoparticles are heated in the presence of selenium and/or sulfur on the conductive substrate, the materials combine to form a CIGS or CIGSS photon-absorbing layer. The resulting nanoparticles become partially fused or “necked”. Although the layer is uniform and continuous, the nanoparticles largely retain their discrete size and shape, and thus high surface area.

Photovoltaic cell efficiency is highly dependent on the cell's ability to efficiently absorb photons and transmit electrons. In some cases, poor efficiency is caused by layer defects in CIGS or CIGSS photon absorbing material formed during the heating process and non-uniform distribution of material. Although thicker layers have the potential to absorb more photons, they are also more susceptible to these defects. However, when a highly active, thin, defect-free layer is applied, efficiency is highest. To optimize PV efficiency, the photovoltaic absorbing layer should be as thin as possible to decrease the likelihood of defects in the layer. Thus, another aspect of at least one of the embodiments includes the idea that by using metal alloy nanoparticles as the starting materials, there is greater control over layer thickness and the potential to produce a thin layer, less than 500 nm in thickness.

The reactive metal alloy nanoparticles are preferably formed by a vapor condensation process such as that described in U.S. Pat. No. ______ [Ser. No. 10/840,109], the entire contents of which is hereby expressly incorporated by reference. With such a process, material may be fed onto a heater element so as to vaporize the material, allowing the material vapor to flow upwardly from the heater element in a controlled substantially laminar manner under free convection, injecting a flow of cooling gas upwardly from a position below the heater element, preferably parallel to and into contact with the upward flow of the vaporized material and at the same velocity as the vaporized material, allowing the cooling gas and vaporized material to rise and mix sufficiently long enough to allow nano-scale particles of the material to condense out of the vapor, and drawing the mixed flow of cooling gas and nano-scale particles with a vacuum into a storage chamber. Binary, tertiary, or ternary metal nanoparticle alloys of Groups IB, IIB and/or Groups IIIA on the periodic table preferably have a particle size of less than 50 nanometers, and can be so more reliably when prepared by a vapor condensation process.

For further efficiency optimization, the band gap energy of the photovoltaic absorbing layer can be modified by stratifying the amount of gallium, where a higher gallium concentration is located closer to the substrate and a lower concentration closer to the photon-absorbing and emission layer interfact (p-n junction). This can be accomplished via multiple layers of nano-scale metal alloy particles with a different gallium concentration in each layer. By applying these layers with subsequent selenization and sulfidization, a graded absorber layer is produced, and the sum of all layers in still less than 0.5 microns in thickness. This methodology has an added benefit in that surface contact is enhanced at the p-n junction, as cadmium sulfide and gallium repel each other. An example also shown in FIG. 1. Base material 101 is typically glass or metal foil, however plastic is most preferable so that the cells have increased flexibility. Upon the base material, substrate foil 102 is deposited and used as a back contact, and is preferably a metal foil and most preferably molybdenum. First, gallium-rich CIG layer 111 is then deposited onto foil 102. Subsequent CIG layers are then deposited, each with decreased gallium concentration. A final, gallium-free layer 112 is applied. The total sum of layers 113 has a maximum thickness of 500 nm. These deposited layers are then heated and then reacted with elements from Group VA and/or IVA. To permit the flow of electrons through the cell, an n-type electron transporting cadmium sulfide emission layer 104 is then applied on top of photon-absorbing layers 113. An anti-reflective coating of zinc oxide 105 is applied on top of emission layer 104. This layer is both electrically and optically conductive, allowing photons to reach photon-absorbing layers 113. Electrical contact 106 is applied to complete circuit 107 with foil 102 to collect and use the energy gained from light absorption. Furthermore, an environmental protection layer is placed on top of anti-reflective coating 108 and electrical contact 106 to prevent and protect against weathering.

### EXAMPLE

### Preparation of CIGS

Copper (19.278 g), indium (80.36 g), and gallium (20.916 g) were mixed in a graphite crucible under argon at 800° C., stirred to mix, and allowed to cool. The resulting ingot was crushed into a powder. This powder was further reacted in a vapor condensation reactor at 1400° C. for one hour to yield copper-indium-gallium alloy nanoscale particles, with a final composition of Cu₁In_{0.7}Ga_{0.3}. A portion of the resulting nanoscale alloy (0.778 g) was placed in a graphite crucible and selenium (0.898 g) was added. The crucible was covered with a graphite lid, then placed in an oven and heated to 500° C. for 75 minutes in an inert atmosphere. The resulting CIGS photovoltaic absorber material was allowed to cool to room temperature.

The foregoing description is that of preferred embodiments having certain features, aspects, and advantages in accordance with the present inventions. Various changes and modifications also may be made to the above-described embodiments without departing from the spirit and scope of the inventions.

What is claimed is

1. A photovoltaic cell comprising:
a photon-absorbing layer comprising metal alloy nanoparticles substantially fused together, the nanoparticles comprising the formula Cu₁In₁₋ₓGaₓ, where x ranges from 0 to 1, said layer having been prepared by heating the nanoparticles sufficiently to permit reaction with material comprising either selenium and/or sulfur;
an electrically conductive substrate supporting the photon-absorbing layer and providing at least a portion of an electrical circuit in combination with said photon-absorbing layer;
an emitting layer comprising material capable of absorbing electrons from the photon-absorbing layer; and
an anti-reflective coating comprising material suitable for permitting a significant amount of sunlight that strikes the cell to reach the photon-absorbing layer.

2. The photovoltaic cell of claim 1, further comprising an environmental protection layer to reduce environmental degradation of the cell during use.

3. The photovoltaic cell of claim 1, wherein the layer is less than about 1 micron.

4. The photovoltaic cell of claim 1, wherein the layer is less than about 500 nanometers.

5. The photovoltaic cell of claim 1 wherein the anti-reflective coating comprises zinc oxide.

6. The photovoltaic cell of claim 1, wherein the emitting layer comprises cadmium sulfide.

7. The photovoltaic cell of claim 2, wherein the environmental protection layer further comprises glass having a low iron content.

8. The photovoltaic cell of claim 1, wherein a substantial portion of the nanoparticles are less than about 50 nanometers.

9. The photovoltaic cell of claim 1, wherein the photon-absorbing layer comprises nanoparticles created using a vapor condensation process.

10. A method of preparing an electronic device, the method comprising:
mixing on an electrically conductive substrate particles comprising at least one element selected from Groups VA and/or VIA with metal alloy nanoparticles made from a vapor condensation process; and
heating the mixture to at least a reaction temperature that is sufficient to create a substantially fused layer of nanosized particles.

11. The method of claim 10, wherein the resulting layer comprises chalcopyrite.

12. The method of claim 10, wherein a substantial portion of the metal alloy nanoparticles are less than 50 nm.

13. The method of claim 10, wherein the resulting layer is suitable for use in a photovoltaic cell.

14. The method of claim 10, wherein the heating step comprises heating the mixture to a temperature of at least 250° C.

15. The method of claim 10, wherein the resulting layer is less than about 1 micron.

16. The method of claim 10, wherein the resulting layer is less than about 500 nanometers.

17. The method of claim 10, wherein the resulting layer is less than about 500 nanometers on average.

18. A composition having photon-absorbing characteristics, the composition comprising metal alloy nanoparticles made from a vapor condensation process, the composition suitable for use in an electronic device.

19. The composition of claim 18, wherein the metal alloy nanoparticles are comprised of at least one metal from group IB, IIB, or IIIA.

20. The composition of claim 19, wherein the metal alloy nanoparticles comprises at least one of copper, indium, or gallium.

21. The composition of claim 18, wherein a substantial portion of the metal alloy nanoparticles is less than 50 nm.

22. The composition of claim 18, wherein at least some of the metal alloy nanoparticles have an oxide shell.

23. The composition of claim 18, wherein the metal alloy nanoparticles have sufficiently high reactivity to permit reaction with material from either Group VA and/or VIA in the gas, liquid, or solid state.

24. The composition of claim 23, wherein the material comprises either elemental selenium and/or sulfur.

25. A photovoltaic cell comprising:
a photon-absorbing layer comprising copper-indium alloy nanoparticles substantially fused together, said layer prepared by heating the nanoparticles sufficiently to permit reaction with material comprising either Group VA and/or VIA;
an electrically conductive substrate supporting the photon-absorbing layer and providing at least a portion of an electrical circuit in combination with said layer;
an emitting layer comprising material capable of absorbing electrons from the photon-absorbing layer; and
an anti-reflective coating comprising material suitable for permitting a significant amount of sunlight that strikes the cell to reach the photon-absorbing layer.

26. The photovoltaic cell of claim 25, wherein the photon-absorbing layer is less than about 0.5 microns thick.

27. The photovoltaic cell of claim 25, further comprising an environmental protection layer to reduce environmental degradation of the cell during use.

28. The photovoltaic cell of claim 25 wherein the Group. VA and/or VIA material comprises either selenium and/or sulfur.

29. The photovoltaic cell of claim 25 wherein the photon-absorbing layer further comprises gallium.

30. The photovoltaic cell of claim 25 wherein the anti-reflective coating comprises zinc oxide.

31. The photovoltaic cell of claim 25 wherein the emitting layer comprises cadmium sulfide.

32. The photovoltaic cell of claim 25 wherein the environmental protection layer further comprises glass having a low iron content.

33. A stratified layer of metal alloy nanoparticles comprising the formula Cu₁In₁₋ₓGaₓ.

34. The layer of claim 33, wherein the gallium concentration in at least one of the stratifications is different from the gallium concentration in another stratification.

35. The composition of claim 33, wherein x ranges from 0 to 1.

36. The composition of claim 33, wherein the concentration of gallium is lower proximal to the emitting layer.

37. The composition of claim 33, wherein there are a minimum of three stratifications and a maximum of twenty stratifications.

38. The layer of claim 33, wherein the thickness is less than about 1 micron.

39. The layer of claim 33, wherein the average thickness is less than about 500 nanometers.
